(19) United States
(12) Patent Application Publication
(10) Pub. No.: US 2026/0304803 A1
(43) Pub. Date: Oct. 1, 2026

(54) SEMICONDUCTOR DEVICE AND METHOD FOR MANUFACTURING SEMICONDUCTOR DEVICE

(71) Applicant: JUSUNG ENGINEERING CO., LTD., Gwangju-si, Gyeonggi-do (KR)

(72) Inventors: Won Tae CHO, Gwangju-Si, Gyeonggi-do (KR); Chul Joo HWANG, Gwangju-Si, Gyeonggi-do (KR)

(21) Appl. No.: 19/478,422

(22) PCT Filed: May 9, 2024
(86) PCT No.: PCT/KR2024/006251

§ 371 Date: Oct. 24, 2025

(30) Foreign Application Priority Data
May 10, 2023 (KR) 10-2023-0060722

(51) Int. Cl. H10D 1/68; H10D 1/00; H10P 14/43

(52) U.S. Cl. CPC H10D 1/696; H10D 1/041; H10P 14/43

(57) ABSTRACT

A semiconductor device according to an embodiment of the present invention includes an electrode formed on a substrate and including a noble metal-containing layer, a dielectric layer formed on one surface of the noble metal-containing layer, and a capping layer formed between the noble metal-containing layer and the dielectric layer and containing titanium (Ti). Therefore, according to embodiments of the present invention, it is possible to suppress or prevent occurrence of defects at an interface between the electrode and the dielectric layer. Accordingly, a reduction in the dielectric constant of the dielectric layer may be suppressed or prevented, and the dielectric constant of the dielectric layer may be uniform. Further, the bonding force of the dielectric layer may be enhanced.

### TECHNICAL FIELD

The present disclosure relates to a semiconductor device and a method for manufacturing the semiconductor device, and more particularly, to a semiconductor device capable of improving its properties and a method for manufacturing the semiconductor device.

### BACKGROUND ART

A capacitor includes a lower electrode formed on a substrate, a dielectric layer formed on the lower electrode, and an upper electrode formed on the dielectric layer. The lower electrode is formed of ruthenium (Ru), and the dielectric layer is formed by depositing, on the lower electrode, ZrO₂ or HfO₂, an oxide having a high dielectric constant.

However, if the dielectric layer is formed on the lower electrode, oxygen contained in the dielectric layer diffuses or moves toward the lower electrode. As a result, the oxygen concentration at the interface between the dielectric layer and the lower electrode increases, which causes the generation of interface defects. As a result, dielectric properties of the dielectric layer are degraded. That is, there is a problem in that the dielectric constant of the dielectric layer decreases, or the dielectric constant becomes non-uniform. In addition, adhesion between the dielectric layer and the lower electrode is degraded. In addition, due to the degradation in the dielectric properties of the dielectric layer and the degradation in the adhesion, properties of the capacitor are degraded.

### PRIOR ART DOCUMENT

(Patent Document 1) Korean Patent Registration No. KR 10-0881728

### DISCLOSURE OF THE INVENTION

### Technical Problem

The present disclosure provides a semiconductor device capable of suppressing or preventing defects from occurring between an electrode and a dielectric layer, and a method for manufacturing the semiconductor device.

The present disclosure also provides a semiconductor device capable of improving dielectric properties of a dielectric layer, and improving adhesion between an electrode and the dielectric layer, and a method for manufacturing the semiconductor device.

### Technical Solution

In accordance with an exemplary embodiment, a semiconductor device includes an electrode formed on a substrate, and including a precious metal-containing layer, a dielectric layer formed on one surface of the precious metal-containing layer, and a capping layer formed between the precious metal-containing layer and the dielectric layer, and containing titanium (Ti).

The capping layer may be formed as at least one of a titanium metal layer, a titanium oxide layer, a titanium nitride layer, or a titanium oxynitride layer.

The thickness of the capping layer may be approximately 10 Å or less.

The precious metal-containing layer may contain at least one of ruthenium (Ru), platinum (Pt), gold (Au), silver (Ag), rhodium (Rh), palladium (Pd), osmium (Os), iridium (Ir), yttrium (Y), or molybdenum (Mo).

The precious metal-containing layer may be either a precious-metal metal layer or precious-metal oxide layer containing at least one of ruthenium (Ru), platinum (Pt), gold (Au), silver (Ag), rhodium (Rh), palladium (Pd), osmium (Os), iridium (Ir), yttrium (Y), or molybdenum (Mo).

The precious-metal containing layer may include a first precious metal-containing layer and a second precious metal-containing layer formed on the first precious metal-containing layer, wherein one of the first and second precious metal-containing layers may be a precious-metal metal layer and the other one thereof may be a precious-metal oxide layer.

The electrode may include a titanium nitride layer formed on the other surface of the precious metal-containing layer.

In accordance with another exemplary embodiment, a method for manufacturing a semiconductor device includes spraying a precursor containing a precious metal onto a substrate to form an electrode including a precious metal-containing layer, spraying a precursor containing titanium (Ti) toward the electrode to form a capping layer on the electrode, and forming a dielectric layer on the capping layer.

The forming of the capping layer may include exposing a titanium-containing layer formed by spraying the precursor containing titanium (Ti) to hydrogen plasma.

The method may further include spraying a reactant gas including at least one of oxygen and nitrogen toward the titanium-containing layer formed by spraying the precursor containing titanium (Ti).

The spraying of the reactant gas may include generating plasma using the reactant gas.

The spraying of the precursor containing a precious metal may be spraying a precursor containing at least one of ruthenium (Ru), platinum (Pt), gold (Au), silver (Ag), rhodium (Rh), palladium (Pd), osmium (Os), iridium (Ir), yttrium (Y), or molybdenum (Mo).

The forming of the electrode layer may include, after spraying the precursor containing a precious metal, generating hydrogen plasma.

The forming of the electrode layer may include, after spraying the precursor containing a precious metal, generating oxygen plasma.

The forming of the electrode may include, before forming the precious metal-containing layer on the substrate, forming a titanium nitride layer on the substrate.

### ADVANTAGEOUS EFFECTS

According to embodiments of the present invention, it is possible to suppress or prevent defects from occurring at the interface between an electrode and a dielectric layer. As a result, it is possible to suppress or prevent the dielectric constant of the dielectric layer from decreasing, and to allow the dielectric constant of the dielectric layer to be uniform. In addition, it is possible to improve the bonding force of the dielectric layer.

### BRIEF DESCRIPTION OF THE DRAWINGS

FIG. 1 is a diagram conceptually showing a semiconductor device in accordance with an exemplary embodiment;
(a) to (d) of FIG. 2 are process diagrams sequentially showing a method of manufacturing a semiconductor device in accordance with the exemplary embodiment;

FIG. 3 is a diagram conceptually showing a semiconductor device in accordance with an embodiment modified from the exemplary embodiment; and

FIG. 4 is a diagram conceptually showing a semiconductor device in accordance with another exemplary embodiment.

### MODE FOR CARRYING OUT THE INVENTION

Hereinafter, embodiments of the present invention will be described in more detail with reference to the accompanying drawings. However, the present invention is not limited to the embodiments disclosed below, but will be implemented in various forms different from each other, and the embodiments are merely to complete the present invention, and are provided to fully convey the scope of the present invention to those skilled in the art. The drawings may be exaggerated to describe the embodiments of the present invention, and like reference numerals in the drawings refer to like elements.

FIG. 1 is a diagram conceptually showing a semiconductor device in accordance with an exemplary embodiment.

The semiconductor device may be a device including an electrode containing a precious metal and a dielectric layer formed on the electrode. More specifically, the semiconductor device may be a capacitor.

Referring to FIG. 1, the capacitor may include a substrate S, a lower electrode 100 formed on the substrate S, a dielectric layer 300 formed on the lower electrode 100, a capping layer 200 formed between the lower electrode 100 and the dielectric layer 300, and an upper electrode 400 formed on the dielectric layer 300.

The substrate S may be either a wafer or glass. If the substrate S is a wafer, the substrate S may be one of a Si wafer, a GaAs wafer, and a SiGe wafer. Of course, as the wafer used as the substrate S, a variety of wafers other than the types of the wafers described above may be used.

The dielectric layer 300 is formed on the lower electrode 100, and may be formed as an oxide layer having a high dielectric constant. As a more specific example, the dielectric layer 300 may be formed of at least one of ZrO₂, HfO₂, Al₂O₃, TiO₂, or TaO₂.

At least one of the lower electrode 100 and the upper electrode 400 may be formed to contain a precious metal. In other words, at least one of the lower electrode 100 and the upper electrode 400 may be formed as a precious metal-containing layer. As a more specific example, at least one of the lower electrode 100 and the upper electrode 400 may be formed to contain ruthenium (Ru), which is a precious metal. That is, at least one of the lower electrode 100 and the upper electrode 400 may be formed as a ruthenium-containing layer.

Of course, the precious metal contained in at least one of the lower electrode 100 and the upper electrode 400 is not limited to ruthenium (Ru) described above, but a variety of precious metal materials may be applied. That is, at least one of the lower electrode 100 and the upper electrode 400 may be formed to contain at least one of ruthenium (Ru), platinum (Pt), gold (Au), silver (Ag), rhodium (Rh), palladium (Pd), osmium (Os), iridium (Ir), yttrium (Y), or molybdenum (Mo).

Hereinafter, an example in which the lower electrode 100 and the upper electrode 400 is formed to contain a precious metal will be described. In addition, ruthenium (Ru) will be described as an example of the precious metal.

The dielectric layer 300 is formed as an oxide layer as described above, and for example, may be formed of any one among ZrO₂, HfO₂, Al₂O₃, TiO₂, and TaO₂. In addition, the dielectric layer 300 is formed by being deposited on the lower electrode 100 containing a precious metal, for example, ruthenium. However, when the dielectric layer 300 is formed on the lower electrode 100, oxygen contained in the dielectric layer 300 may diffuse or move toward the lower electrode 100. As a result, the oxygen concentration at the interface between the dielectric layer 300 and the lower electrode 100 increases, which may cause the generation of interface defects. As a result, dielectric properties of the dielectric layer 300 are degraded. That is, there is a problem in that the dielectric constant of the dielectric layer 300 decreases, or the dielectric constant becomes non-uniform in the direction of the thickness of the dielectric layer 300. In addition, adhesion between the dielectric layer 300 and the lower electrode 100 may be degraded. In addition, due to the degradation in the dielectric properties of the dielectric layer 300 and the degradation in the adhesion, properties of the capacitor may be degraded.

Therefore, in an embodiment, in order to suppress or prevent the degradation in the dielectric properties of the dielectric layer 300 or the decrease in the adhesion of the dielectric layer 300, the capping layer 200, which is a layer containing titanium (Ti), is formed between the lower electrode 100 containing a precious metal and the dielectric layer 300. The capping layer 200 may be formed as at least one of a titanium (Ti) metal layer, a titanium nitride (TiN) layer, a titanium oxide (TiO) layer, or a titanium oxynitrid (TiON) layer.

FIGS. 2A-2D are process diagrams sequentially showing a method of manufacturing a semiconductor device in accordance with the exemplary embodiment.

Hereinafter, referring to FIGS. 2A-2D, the method of manufacturing a semiconductor device in accordance with the exemplary embodiment will be described.

Referring to FIGS. 2A-2D, a step for manufacturing a semiconductor device may include (a) forming a lower electrode 100 on a substrate S, (b) forming a capping layer 200 on the lower electrode 100, (c) forming a dielectric layer 300 on the capping layer 200, and (d) forming an upper electrode 400 on the dielectric layer 300.

The lower electrode 100 may be formed as a layer containing a precious metal. As a more specific example, the lower electrode 100 may be formed as a layer containing ruthenium (Ru) (ruthenium-containing layer), which is a precious metal. Here, the ruthenium-containing layer may be either a ruthenium (Ru) metal layer or a ruthenium oxide (RuO₂) layer. In other words, the lower electrode 100 may include a ruthenium metal layer, or may include a ruthenium oxide layer.

Hereinafter, an example in which the lower electrode 100 is formed as a ruthenium-containing layer, and the ruthenium-containing layer is a ruthenium metal layer will be described. That is, in describing the manufacturing method of a semiconductor device, an example in which the lower electrode 100 is formed as a ruthenium metal layer will be described. In addition, for the convenience of explanation, the lower electrode 100 formed as a ruthenium-containing layer will be simply named and described as a ‘ruthenium-containing layer.’ In addition, in describing the ruthenium-containing layer, the ruthenium-containing layer will be referred to as ‘100,’which is the same reference numeral as that of the lower electrode 100.

A step of forming the ruthenium-containing layer 100 (the step of forming the lower electrode) may include spraying a ruthenium-containing precursor toward the substrate S to deposit the ruthenium-containing layer 100 (ruthenium-containing precursor spraying step), and exposing the ruthenium-containing layer 100 to hydrogen plasma (hydrogen plasma exposure step).

In addition, the ‘ruthenium-containing precursor spraying step-hydrogen plasma exposure step’ may be set as one cycle (hereinafter, a ruthenium-containing layer formation cycle CY_{Ru}). That is, the step of forming the ruthenium-containing layer 100 includes the ruthenium-containing layer formation cycle CY_{Ru}, and the ruthenium-containing layer formation cycle CY_{Ru} may include the steps of spraying a ruthenium-containing precursor and exposing the ruthenium-containing layer 100 to hydrogen plasma.

In addition, the step of forming the ruthenium-containing layer 100 may further include at least one of spraying a purge gas between the ruthenium-containing precursor spraying step and the hydrogen plasma exposure step (a primary purge step) and spraying a purge gas after the hydrogen plasma exposure step (a secondary purge step). Here, an argon (Ar) gas may be used as the purge gas. In this case, the ‘ruthenium-containing precursor spraying step-primary purge step-hydrogen plasma exposure step-secondary purge step’ may be set as one cycle (the ruthenium-containing layer formation cycle CY_{Ru}). That is, the step of forming the ruthenium-containing layer 100 includes the ruthenium-containing layer formation cycle CY_{Ru}, and the ruthenium-containing layer formation cycle CY_{Ru} may include the ruthenium-containing precursor spraying step, the primary purge step, the hydrogen plasma exposure step, and the secondary purge step. At this time, in the ruthenium-containing layer formation cycle CY_{Ru}, at least one of the primary purge step and the secondary purge step may be omitted.

In addition, the ruthenium-containing layer formation cycle CY_{Ru} described above may be performed a plurality of times. That is, the step of forming the ruthenium-containing layer 100 may include a plurality of the ruthenium-containing layer formation cycles CY_{Ru}.

Hereinafter, the ruthenium-containing layer formation cycle CY_{Ru} will be described in more detail. In the step of spraying a ruthenium-containing precursor, a precursor containing or including ruthenium is sprayed toward the substrate S. That is, a precursor containing ruthenium is sprayed into a chamber in which the substrate S is charged. Here, a precursor raw material containing ruthenium (Ru) may be, for example, bis(ethylcyclopentadienyl)ruthenium ((EtCp)₂Ru). Of course, the precursor raw material containing ruthenium (Ru) is not limited to the material described above, but a variety of precursor raw materials containing ruthenium (Ru) may be used.

When the precursor containing ruthenium (Ru) is sprayed toward the substrate S, the precursor is deposited or adsorbed on one surface of the substrate S, so that a layer containing ruthenium is deposited. In other words, a ruthenium metal layer is deposited.

After the step of spraying the precursor is completed, the primary purge is performed by spraying a purge gas into the chamber in which the substrate S is charged. At this time, for example, an argon (Ar) gas may be used as the purge gas.

After the primary purge is completed, the ruthenium-containing layer 100 is exposed to hydrogen plasma. That is, hydrogen plasma is generated inside the chamber in which the substrate S with the ruthenium-containing layer 100 is charged, so that the ruthenium-containing layer 100 is exposed to the hydrogen plasma. To this end, radio frequency (RF) power is applied to at least one of a susceptor on which the substrate S is seated inside the chamber and a spraying part for spraying a gas into the chamber. In addition, a gas containing hydrogen (H₂) is used as a gas for generating plasma. More specifically, the gas for generating plasma may be a hydrogen (H₂) gas. As described above, when the RF power is applied and the gas containing hydrogen (H₂) is sprayed, plasma containing the hydrogen (H₂), that is, hydrogen plasma, may be generated inside the chamber. Accordingly, the substrate S with the ruthenium-containing layer 100 is exposed to the hydrogen plasma.

As described above, the hydrogen plasma exposure step is a step in which hydrogen plasma is generated to expose the ruthenium-containing layer 100 to the hydrogen plasma. Therefore, the hydrogen plasma exposure step may be named as a hydrogen plasma generation step.

The ruthenium-containing precursor may contain impurities. For example, the ruthenium-containing precursor may include at least one ligand of C (carbon) and O (oxygen) other than ruthenium (Ru). Accordingly, the ruthenium-containing layer 100 deposited by spraying the ruthenium-containing precursor may contain or include at least one ligand of C (carbon) and O (oxygen), and the ligand is an impurity that increases the resistivity of the ruthenium-containing layer 100. Therefore, it is preferable that the impurity included in the ruthenium-containing layer 100 are removed.

Therefore, in an embodiment, the ruthenium-containing precursor is sprayed to deposit the ruthenium-containing layer 100, and then, the ruthenium-containing layer 100 is exposed to hydrogen plasma to remove impurities. When the ruthenium-containing layer 100 is exposed to the hydrogen plasma, the impurities included in the ruthenium-containing layer 100 react with hydrogen. Accordingly, at least one of the impurities of C (carbon) and O (oxygen) included in the ruthenium-containing layer 100 reacts with the hydrogen and becomes a gas and escapes from the ruthenium-containing layer 100. Therefore, the content of at least one of the impurities of C (carbon) and O (oxygen) included in the ruthenium-containing layer 100 is reduced. As a result, the resistivity of the ruthenium-containing layer 100 may be lowered.

Thereafter, the secondary purge is performed by spraying a purge gas into the chamber in which the substrate S is charged. At this time, the same gas as the gas used in the primary purge may be used as the purge gas, and for example, an argon (Ar) gas may be used.

A process including the ruthenium-containing precursor spraying step, the primary purge step, the hydrogen plasma exposure step, and the secondary purge step described above may be set as one ruthenium-containing layer formation cycle CY_{Ru}. That is, the cycle for forming the ruthenium-containing layer 100 CY_{Ru} may include the ‘ruthenium-containing precursor spraying step—primary purge step—hydrogen plasma exposure step-secondary purge step.’ In addition, the ruthenium-containing layer formation cycle CY_{Ru} may be performed a plurality of times to form the ruthenium-containing layer 100 with a target thickness as shown in (a) of FIG. 2. That is, a ruthenium metal layer is formed on the substrate S. In other words, the lower electrode 100 composed of the ruthenium metal layer is formed on the substrate S.

Next, the capping layer 200 is formed on the ruthenium-containing layer 100. The capping layer 200 may be formed as a titanium (Ti)-containing layer, and the titanium-containing layer may be formed as any one among a titanium metal layer, a titanium oxide (TiO) layer, a titanium nitride (TiN) layer, and a titanium oxynitrid (TiON) layer. Hereinafter, an example in which the capping layer 200 is formed as a titanium metal layer will be described.

A step of forming the capping layer 200 may include spraying a titanium-containing precursor toward the ruthenium-containing layer 100 to deposit the capping layer 200 (titanium-containing precursor spraying step), and exposing the titanium-containing layer 200 to hydrogen plasma (hydrogen plasma exposure step).

In addition, the ‘titanium-containing precursor spraying step-hydrogen plasma exposure step’ may be set as one cycle (hereinafter, a capping layer formation cycle CY_{C}). That is, the step of forming the capping layer 200 includes the capping layer formation cycle CY_{C}, and the capping layer formation cycle CY_{C} may include the steps of spraying a titanium-containing precursor and exposing the capping layer 200 to hydrogen plasma.

In addition, the step of forming the capping layer 200 may further include at least one of spraying a purge gas between the titanium-containing precursor spraying step and the hydrogen plasma exposure step (a primary purge step) and spraying a purge gas after the hydrogen plasma exposure step (a secondary purge step). In this case, the ‘titanium-containing precursor spraying step-primary purge step-hydrogen plasma exposure step-secondary purge step’ may be set as one cycle (the capping layer formation cycle CY_{C}). That is, the step of forming the capping layer 200 includes the capping layer formation cycle CY_{C}, and the capping layer formation cycle CY_{C} may include the titanium-containing precursor spraying step, the primary purge step, the hydrogen plasma exposure step, and the secondary purge step. At this time, in the capping layer formation cycle CY_{C}, at least one of the primary purge step and the secondary purge step may be omitted.

In addition, the capping layer formation cycle CY_{C} described above may be performed a plurality of times. That is, the step of forming the capping layer 200 may include a plurality of the capping layer formation cycles CY_{C}.

Hereinafter, the capping layer formation cycle CY_{C} will be described in more detail. In the step of spraying a titanium-containing precursor, a precursor containing or including titanium is sprayed toward the substrate S. That is, a precursor containing titanium is sprayed into a chamber in which the substrate S is charged. Here, a precursor raw material containing titanium may be, for example, tetrakis(dimethylamino)titanium (TiTDMAT: C₈H₂₄N₄). Of course, the precursor raw material containing titanium is not limited to the material described above, but a variety of precursor raw materials containing titanium may be used.

When the precursor containing titanium is sprayed toward the substrate S, the precursor is deposited or adsorbed on one surface of the substrate S as shown in (b) of FIG. 2, so that a layer containing titanium is deposited. That is, a titanium metal layer is deposited. In other words, the capping layer 200 formed as the titanium metal layer is formed.

After the step of spraying the titanium-containing precursor is completed, the capping layer 200 is exposed to hydrogen plasma. The hydrogen plasma is generated in the same manner as described in the ruthenium-containing layer formation cycle CY_{Ru}, and thus, the description thereof is omitted.

The titanium-containing precursor may contain an impurity, and the impurity may be, for example, any one ligand of C (carbon) and O (oxygen). Accordingly, the capping layer 200 formed by spraying the titanium-containing precursor may contain or include impurities, and the impurities may degrade the performance of a semiconductor device. Therefore, it is preferable that the impurities included in the capping layer 200 are removed.

Accordingly, in an embodiment, the titanium-containing precursor is sprayed to deposit the capping layer 200, and then, the capping layer 200 is exposed to hydrogen plasma to remove impurities. When the capping layer 200 is exposed to the hydrogen plasma, the impurities included in the capping layer 200 react with hydrogen. For example, at least one of impurities of C (carbon) and O (oxygen) included in the capping layer 200 reacts with the hydrogen and becomes a gas and escapes from the capping layer 200. Accordingly, the content of the impurities in the capping layer 200 is reduced.

Thereafter, the secondary purge is performed by spraying a purge gas, e.g., an argon (Ar) gas, into the chamber in which the substrate S is charged.

A process including the titanium-containing precursor spraying step, the primary purge step, the hydrogen plasma exposure step, and the secondary purge step described above may be set as one capping layer formation cycle CY_{C}. That is, the cycle CY_{C} for forming the capping layer 200 may include the ‘titanium-containing precursor spraying step-primary purge step hydrogen plasma exposure step-secondary purge step.’ In addition, the capping layer formation cycle CY_{C} may be continuously performed a plurality of times to form the capping layer 200 with a target thickness as shown in (b) of FIG. 2. At this time, it is preferable that the capping layer 200 is formed to a thickness of approximately 10 Å or less, more preferably approximately 1 Å to approximately 10 Å.

Meanwhile, if the thickness of the capping layer 200 is greater than approximately 10 Å, there is a problem in that the overall thickness of the capacitor increases. That is, it is preferable that a capacitor is thin but has a high capacity, but if the thickness of the capacitor is greater than approximately 10 Å, there is a problem in that the overall thickness of the capacitor increases. On the contrary, if the thickness of the capping layer 200 is less than approximately 1Å, it may not be possible to suppress or prevent oxygen contained in the dielectric layer 300 using the capping layer 200 from moving toward the capping layer 200 or the lower electrode 100. As a result, the dielectric constant of the dielectric layer 300 may decrease, or the dielectric constant of the dielectric layer 300 may not be uniform in the thickness direction.

Thereafter, the dielectric layer 300 is formed on the capping layer 200 as shown in (c) of FIG. 2. As a more specific example, zirconia (ZrO₂) is deposited on the capping layer 200 to form the dielectric layer 300. In forming the dielectric layer 300, the dielectric layer 300 is formed on the capping layer 200 as described above. That is, before forming the dielectric layer 300, the capping layer 200 containing titanium is formed on the ruthenium-containing layer 100, and the dielectric layer 300 is formed on the capping layer 200. As a result, it is possible to suppress or prevent oxygen contained in the dielectric layer 300 from diffusing or moving toward the capping layer 200 or the ruthenium-containing layer 100. In other words, the capping layer 200 containing titanium may suppress or prevent oxygen contained in the dielectric layer 300 from diffusing or moving toward the capping layer 200 or the ruthenium-containing layer 100.

Therefore, it is possible to suppress or prevent defects caused by oxygen at the interface between the dielectric layer 300 and the lower electrode 100. Accordingly, it is possible to suppress or prevent the dielectric constant of the dielectric layer 300 from decreasing, and to suppress or prevent the dielectric constant of the dielectric layer 300 from being non-uniform. That is, it is possible to allow the dielectric layer 300 to have a high dielectric constant, and to have a uniform dielectric constant in the thickness direction. In addition, it is possible to improve the adhesion between the dielectric layer 300 and the lower electrode 100. Accordingly, it is possible to suppress or prevent the degradation in the properties of the capacitor due to the degradation in the dielectric properties of the dielectric layer 300 and the degradation in the adhesion. That is, in a capacitor including the lower electrode 100 formed using a precious metal, properties of the capacitor may be improved.

Next, the upper electrode 400 is formed on the dielectric layer 300 as shown in (d) of FIG. 2. At this time, the upper electrode 400 may be formed of various materials having conductivity. In addition, the upper electrode 400 may be formed to contain a precious metal in the same manner as the lower electrode 100, and for example, may be formed to contain ruthenium. As described above, if the upper electrode 400 is prepared to contain a precious metal, the capping layer 200 containing titanium may be formed between the upper electrode 400 and the dielectric layer 300.

In the above-described exemplary embodiment, the ruthenium-containing layer 100 has been described as being formed as a ruthenium metal layer. However, the exemplary embodiment is not limited thereto, and the ruthenium-containing layer 100 may be formed as a ruthenium oxide (RuO₂) layer.

Hereinafter, a method for forming the ruthenium oxide (RuO₂) layer will be described. The method for forming the ruthenium oxide (RuO₂) layer is similar to the method for forming the ruthenium metal layer, and differs in that oxygen plasma is generated. Therefore, in describing the method for forming the ruthenium oxide (RuO₂) layer, the same contents as those described in the above-described method for forming a ruthenium metal layer will be omitted or briefly described.

A step of forming the ruthenium oxide layer (step of forming a lower electrode) may include spraying a ruthenium-containing precursor toward the substrate S to deposit a ruthenium metal layer (ruthenium-containing precursor spraying step), and exposing the ruthenium metal layer to oxygen plasma to oxidize the ruthenium metal layer (oxygen plasma exposure step). In addition, the ‘ruthenium-containing precursor spraying step-oxygen plasma exposure step’ may be set as one cycle (hereinafter, a ruthenium-containing layer formation cycle CY_{Ru}).

In addition, the step of forming the ruthenium oxide layer may further include at least one of spraying a purge gas between the ruthenium-containing precursor spraying step and the oxygen plasma exposure step (a primary purge step) and spraying a purge gas after the oxygen plasma exposure step (a secondary purge step). In this case, the ‘ruthenium-containing precursor spraying step-primary purge step-oxygen plasma exposure step-secondary purge step’ may be set as one cycle (the ruthenium-containing layer formation cycle CY_{Ru}). At this time, in the ruthenium-containing layer formation cycle CY_{Ru}, at least one of the primary purge step and the secondary purge step may be omitted.

In addition, the ruthenium-containing layer formation cycle CY_{Ru} described above may be performed a plurality of times. That is, the step of forming the ruthenium-containing layer 100 may include a plurality of the ruthenium-containing layer formation cycles CY_{Ru}.

In the above-described exemplary embodiment, the capping layer 200 has been described as being formed as a titanium metal layer. However, the exemplary embodiment is not limited thereto, and the capping layer may be formed as at least one of a titanium metal layer, a titanium oxide layer, a titanium nitride layer, or a titanium oxynitride layer.

Hereinafter, a method for forming the capping layer 200 formed as a titanium oxide layer will be described. A step of forming the titanium oxide layer (the step of forming the lower electrode 100) may include spraying a titanium-containing precursor toward the substrate S to deposit a titanium metal layer (titanium-containing precursor spraying step), and spraying a reactant gas including oxygen toward the titanium metal layer to form the titanium oxide layer (reactant gas spraying step.) In addition, the ‘titanium-containing precursor spraying step reactant gas spraying step’ may be set as one cycle (hereinafter, the capping layer formation cycle CY_{C}). In addition, in the oxygen-containing reactant gas spraying step, it may be more preferable that the oxygen is used to generate plasma (i.e., oxygen plasma).

In addition, the step for forming the titanium oxide layer may further include at least one of spraying a purge gas between the titanium-containing precursor spraying step and the reactant gas spraying step (a primary purge step) and spraying a purge gas after the reactant gas spraying step (a secondary purge step). In this case, the ‘titanium-containing precursor spraying step primary purge step-reactant gas spraying step-secondary purge step’ may be set as one cycle (the capping layer formation cycle CY_{C}). At this time, in the capping layer formation cycle CY_{C}, at least one of the primary purge step and the secondary purge step may be omitted.

In addition, the capping layer formation cycle CY_{C} described above may be performed a plurality of times. That is, the step of forming the capping layer 200 may include a plurality of the capping layer formation cycles CY_{C}.

As described above, the capping layer 200 may be formed as a titanium nitride layer. A method for forming the titanium nitride layer is similar to the method for forming the titanium oxide layer, and differs in the type of a reactant gas. That is, in forming the titanium nitride layer, a reactant gas including nitrogen is sprayed.

In addition, the capping layer 200 may be formed as a titanium oxynitride layer. A method for forming the titanium oxynitride layer is similar to the method for forming the titanium oxide layer or the method for forming the titanium nitride layer, and in the reactant gas spraying step, a reactant gas including nitrogen and a reactant gas including oxygen are sprayed.

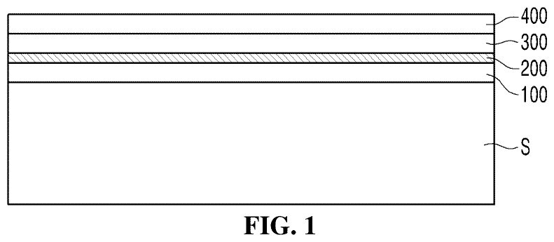

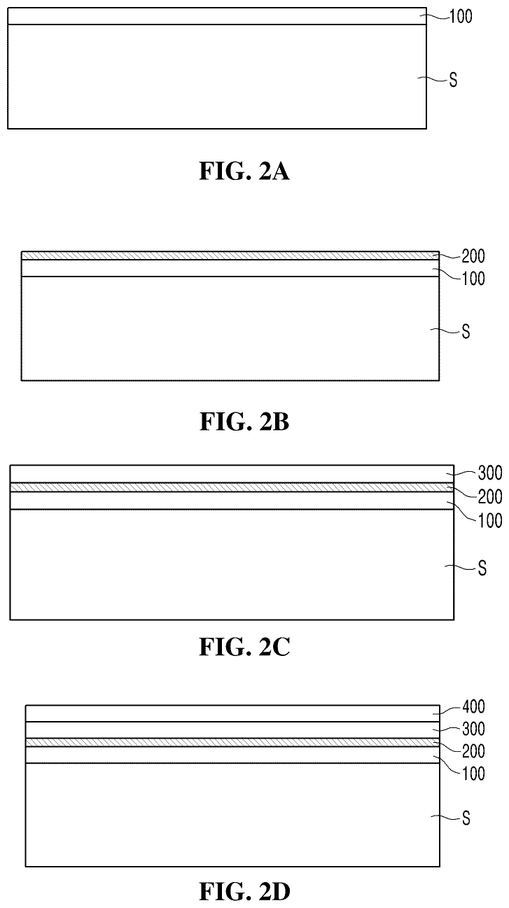

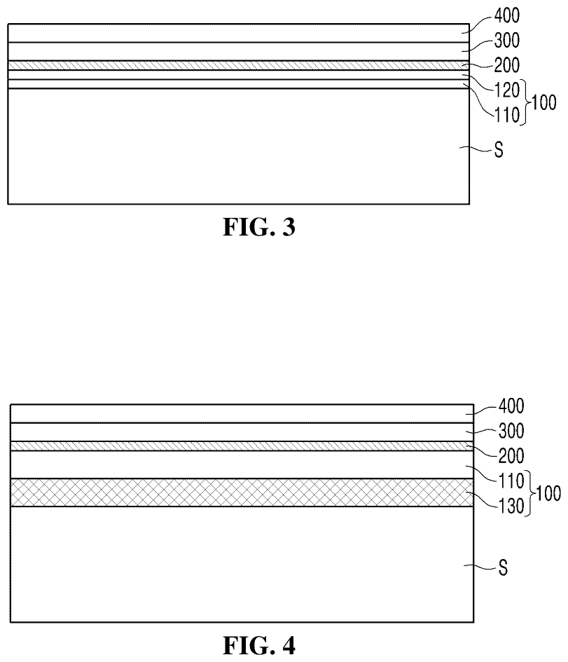

FIG. 3 is a diagram conceptually showing a semiconductor device in accordance with an embodiment modified from the exemplary embodiment.

In the exemplary embodiment, it has been described that the lower electrode 100 is formed as a single ruthenium-containing layer 100. That is, the lower electrode 100 is formed as a ruthenium metal layer, or formed as a ruthenium oxide layer.

However, the exemplary embodiment is not limited thereto, the lower electrode 100 may be formed in a structure in which the ruthenium metal layer and the ruthenium oxide layer are stacked. That is, referring to FIG. 3, the lower electrode 100 may include a first ruthenium-containing layer 110 and a second ruthenium-containing layer 120 formed on the first ruthenium-containing layer 110. Then, the capping layer 200 is formed on the second ruthenium-containing layer 120.

The first ruthenium-containing layer 110 may be a ruthenium oxide layer, and the second ruthenium-containing layer 120 may be a ruthenium metal layer. Of course, the exemplary embodiment is not limited thereto, and the first ruthenium-containing layer 110 may be a ruthenium metal layer, and the second ruthenium-containing layer 120 may be a ruthenium oxide layer.

FIG. 4 is a diagram conceptually showing a semiconductor device in accordance with another exemplary embodiment.

In the exemplary embodiment, it has been described that the lower electrode 100 only includes the ruthenium-containing layer 100. However, the exemplary embodiment is not limited thereto, and the lower electrode 100 may further include a titanium nitride layer 130 formed on a lower side of the ruthenium-containing layer 110. That is, a lower electrode according to the another embodiment may include the titanium nitride layer 130 formed on the substrate S and the ruthenium-containing layer 110 formed on the titanium nitride layer 130. Then, the capping layer 200 is formed on the ruthenium-containing layer 110.

The ruthenium-containing layer 110 may be either a ruthenium metal layer or a ruthenium oxide layer. In addition, he method for forming the titanium nitride layer 130 may be the same as the method for forming the capping layer 200 composed as a titanium nitride layer. Therefore, the description of a method for forming the titanium nitride layer 130 constituting the lower electrode 100 will be omitted.

In the above, it has been described that the lower electrode 100 is formed to contain a precious metal, and the capping layer 200 containing titanium is formed between the lower electrode 100 and the dielectric layer 300. However, the exemplary embodiment is not limited thereto, and the upper electrode 400 may be formed to contain a precious metal, and the capping layer 200 containing titanium may be formed between the upper electrode 400 and the dielectric layer 300. Of course, the lower electrode 100 and the upper electrode 400 may each be formed to contain a precious metal, and the capping layer 200 containing titanium may be formed between the lower electrode 100 and the dielectric layer 300 and between the upper electrode 400 and the dielectric layer 300.

In addition, the precious metal contained in at least one of the lower electrode 100 and the upper electrode 400 is not limited to ruthenium (Ru), but a variety of precious metals may be applied. That is, at least one of the lower electrode 100 and the upper electrode 400 may be formed to contain at least one of ruthenium (Ru), platinum (Pt), gold (Au), silver (Ag), rhodium (Rh), palladium (Pd), osmium (Os), iridium (Ir), yttrium (Y), or molybdenum (Mo).

As described above, in the embodiments, the capping layer 200 containing titanium is formed between an electrode containing a precious metal and the dielectric layer 300. As a result, it is possible to suppress or prevent defects from occurring at the interface between the electrode and the dielectric layer 300. As a result, it is possible to suppress or prevent the dielectric constant of the dielectric layer 300 from decreasing, and to allow the dielectric constant of the dielectric layer 300 to be uniform. In addition, it is possible to improve the bonding force of the dielectric layer 300. Accordingly, it is possible to suppress or prevent the degradation in the properties of the capacitor due to the degradation in the dielectric properties of the dielectric layer 300 and the degradation in the adhesion. That is, in a semiconductor device including the lower electrode 100 formed using a precious metal, properties of the semiconductor device may be improved.

### INDUSTRIAL APPLICABILITY

According to embodiments of the present invention, it is possible to suppress or prevent defects from occurring at the interface between an electrode and a dielectric layer. As a result, it is possible to suppress or prevent the dielectric constant of the dielectric layer from decreasing, and to allow the dielectric constant of the dielectric layer to be uniform. In addition, it is possible to improve the bonding force of the dielectric layer.

What is claimed is:

1. A semiconductor device comprising:
an electrode formed on a substrate, and including a precious metal-containing layer;
a dielectric layer formed on one surface of the precious metal-containing layer; and
a capping layer formed between the precious metal-containing layer and the dielectric layer, and containing titanium (Ti).

2. The semiconductor device of claim 1, wherein the capping layer is formed as at least one of a titanium metal layer, a titanium oxide layer, a titanium nitride layer, or a titanium oxynitride layer.

3. The semiconductor device of claim 1, wherein the thickness of the capping layer is approximately 10 Å or less.

4. The semiconductor device of claim 1, wherein the precious metal-containing layer contains at least one of ruthenium (Ru), platinum (Pt), gold (Au), silver (Ag), rhodium (Rh), palladium (Pd), osmium (Os), iridium (Ir), yttrium (Y), or molybdenum (Mo).

5. The semiconductor device of claim 4, wherein the precious metal-containing layer is either a precious-metal metal layer or precious-metal oxide layer containing at least one of ruthenium (Ru), platinum (Pt), gold (Au), silver (Ag), rhodium (Rh), palladium (Pd), osmium (Os), iridium (Ir), yttrium (Y), or molybdenum (Mo).

6. The semiconductor device of claim 4, wherein the precious-metal containing layer comprises a first precious metal-containing layer and a second precious metal-containing layer formed on the first precious metal-containing layer, wherein one of the first and second precious metal-containing layers is a precious-metal metal layer and the other one thereof is a precious-metal oxide layer.

7. The semiconductor device of claim 1, wherein the electrode comprises a titanium nitride layer formed on the other surface of the precious metal-containing layer.

8. A method for manufacturing a semiconductor device, the method comprising:
spraying a precursor containing a precious metal onto a substrate to form an electrode including a precious metal-containing layer;
spraying a precursor containing titanium (Ti) toward the electrode to form a capping layer on the electrode; and
forming a dielectric layer on the capping layer.

9. The method of claim 8, wherein the forming of the capping layer comprises exposing a titanium-containing layer formed by spraying the precursor containing titanium (Ti) to hydrogen plasma.

10. The method of claim 8, further comprising spraying a reactant gas including at least one of oxygen and nitrogen toward the titanium-containing layer formed by spraying the precursor containing titanium (Ti).

11. The method of claim 10, wherein the spraying of the reactant gas comprises generating plasma using the reactant gas.

12. The method of claim 8, wherein the spraying of the precursor containing a precious metal is spraying a precursor containing at least one of ruthenium (Ru), platinum (Pt), gold (Au), silver (Ag), rhodium (Rh), palladium (Pd), osmium (Os), iridium (Ir), yttrium (Y), or molybdenum (Mo).

13. The method of claim 8, wherein the forming of the electrode comprises, after spraying the precursor containing a precious metal, and then generating hydrogen plasma.

14. The method of claim 8, wherein the forming of the electrode comprises, after spraying the precursor containing a precious metal, generating oxygen plasma.

15. The method of claim 8, wherein the forming of the electrode comprises, before forming the precious metal-containing layer on the substrate, forming a titanium nitride layer on the substrate.
